(19) United States
(12) Patent Application Publication
(10) Pub. No.: US 2025/0385066 A1
(43) Pub. Date: Dec. 18, 2025

(54) HIGH-VOLTAGE COLUMN WITH PERMANENT MAGNET LENS AND POSITIVE WAFER BIAS FOR OVERLAY

(71) Applicant: KLA CORPORATION, Milpitas, CA (US)

(72) Inventors: John GERLING, Livermore, CA (US); Lawrence MURAY, Moraga, CA (US)

(21) Appl. No.: 19/198,085

(22) Filed: May 4, 2025

Related U.S. Application Data
(60) Provisional application No. 63/659,840, filed on Jun. 14, 2024.

(51) Int. Cl. H01J 37/143; H01J 37/244; H01J 37/26

(52) U.S. Cl. CPC H01J 37/143; H01J 37/244; H01J 37/26; H01J 2237/2445; H01J 2237/24475

(57) ABSTRACT

A system includes an electron source that generates an electron beam, a stage that holds a workpiece in a path of the electron beam, a magnetic objective lens disposed in a path of the electron beam, a focus element disposed in the path of the electron beam between the magnetic objective lens and the stage, and a backscattered electron detector disposed in the path of the electron beam between the focus element and the magnetic objective lens. Backscattered electrons, secondary electrons, and x-rays are emitted from the workpiece. The backscattered electrons are measured with the backscattered electron detector.

### CROSS-REFERENCE TO RELATED APPLICATIONS

This application claims priority to the provisional patent application filed Jun. 14, 2024 and assigned U.S. App. No. 63/659,840, the disclosure of which is hereby incorporated by reference.

### FIELD OF THE DISCLOSURE

This disclosure relates to electron beam systems.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Inspection processes are used at various steps during semiconductor manufacturing to detect defects on wafers or other workpieces to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

Defect review typically involves re-detecting defects that were detected by an inspection process and generating additional information about the defects at a higher resolution using either a high magnification optical system or a scanning electron microscope (SEM). Defect review is typically performed at discrete locations on specimens where defects have been detected by inspection. The higher resolution data for the defects generated by defect review is more suitable for determining attributes of the defects such as profile, roughness, or more accurate size information.

Metrology processes also are used at various steps during semiconductor manufacturing to monitor and control the process. Metrology processes are different than inspection processes in that, unlike inspection processes in which defects are detected on wafers or other workpieces, metrology processes are used to measure one or more characteristics of the wafers or other workpieces that cannot be determined using existing inspection tools. Metrology processes can be used to measure one or more characteristics of wafers or other workpieces such that the performance of a process can be determined from the one or more characteristics. For example, metrology processes can measure a dimension (e.g., line width, thickness, etc.) of features formed on the wafers during the process. In addition, if the one or more characteristics of the wafers are unacceptable (e.g., out of a predetermined range for the characteristic(s)), the measurements of the one or more characteristics of the wafers may be used to alter one or more parameters of the process such that additional wafers manufactured by the process have acceptable characteristic(s).

Resolution improvements are needed as device size shrinks. Previous electrostatic lens designs for electron beam systems do not meet resolution requirements at a low landing energy. However, combining permanent magnetic lenses with other electrostatic elements can meet these requirements and can further enable high landing energy on the sample for detection of buried defects. Improved systems and methods are needed.

### BRIEF SUMMARY OF THE DISCLOSURE

A system is provided in a first embodiment. The system includes an electron source that generates an electron beam; a stage configured to hold a workpiece in a path of the electron beam; a magnetic objective lens disposed in the path of the electron beam; a focus element disposed in the path of the electron beam between the magnetic objective lens and the stage; and a backscattered electron detector disposed in the path of the electron beam between the focus element and the magnetic objective lens.

The system may include an extractor disposed in the path of the electron beam between the electron source and the magnetic objective lens. In an instance, the system further includes a secondary electron and backscattered electron detector disposed in the path of the electron beam between the extractor and the magnetic objective lens.

The workpiece may have a positive bias applied using a power source.

The magnetic objective lens may include a permanent magnet.

The backscattered electron detector may define an opening for the electron beam. The opening has a first diameter proximate the magnetic objective lens and a second diameter proximate the focus element. The second diameter is larger than the first diameter.

The electron beam may have a landing energy from 10 kV to 30 kV.

The electron beam may provide a field of view of at least 70 μm.

The system may include a processor in electronic communication with at least the backscattered electron detector.

The system may include an x-ray detector configured to receive x-rays emitted from the workpiece on the stage.

A method is provided in a second embodiment. The method includes generating an electron beam with an electron source. The electron beam is directed through a magnetic objective lens. The electron beam is directed through a backscattered electron detector disposed downstream of the magnetic objective lens in a path of the electron beam. The electron beam is directed through a focus element disposed downstream of the backscattered electron detector in a path of the electron beam. Backscattered electrons, secondary electrons, and x-rays are emitted from a workpiece disposed on a stage downstream of the focus element. The backscattered electrons are measured with the backscattered electron detector.

The method may include determining an image of the workpiece from at least the backscattered electrons using a processor.

The method may include directing the electron beam through an extractor disposed in the path of the electron beam between the electron source and the magnetic objective lens. In an instance, the method may include directing the electron beam through a secondary electron and backscattered electron detector disposed in the path of the electron beam between the extractor and the magnetic objective lens and measuring the x-rays with an x-ray detector. In another instance, the method may include measuring the secondary electrons and the backscattered electrons with the secondary electron and backscattered electron detector.

The method may include applying a positive bias to the workpiece.

The magnetic objective lens may include a permanent magnet.

The backscattered electron detector may define an opening for the electron beam. The opening has a first diameter proximate the magnetic objective lens and a second diameter proximate the focus element. The second diameter is larger than the first diameter.

The electron beam may have a landing energy from 10 kV to 30 kV.

The electron beam may provide a field of view of at least 70 μm.

### DESCRIPTION OF THE DRAWINGS

For a fuller understanding of the nature and objects of the disclosure, reference should be made to the following detailed description taken in conjunction with the accompanying drawings, in which:

FIG. 1 is a block diagram of an electron beam system in accordance with the present disclosure;

FIG. 2 is a diagram of an embodiment of the electron beam system in accordance with the present disclosure;

FIG. 3 is a distribution of backscattered electron modeling used in an example and resulting backscattered electron penetration depths; and

FIG. 4 is a flowchart of a method in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments disclosed herein include an electron beam system with a permanent magnet lens and a positive wafer bias, which can be used for overlay measurements or other workpiece measurements. This can improve resolution at low landing energies and can enable changes to the extraction field.

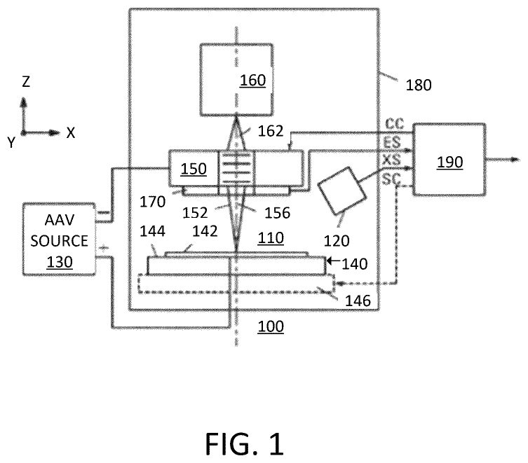

FIG. 1 is a block diagram showing an example of an electron beam system 100, such as a scanning electron microscopy and energy dispersive spectroscopy apparatus in accordance with this disclosure. Electron beam system 100 includes an SEM 110, x-ray detector 120, and an auxiliary acceleration voltage (AAV) source 130. SEM 110 includes a sample holder 140, and a layered electron beam column 150. The layered electron beam column 150 is arranged to output an electron beam 152 towards sample holder 140 at an initial beam energy. The layered electron beam column 150 has a column axis 156 along which electron beam 152 in its undeflected state is output.

The SEM 110 additionally includes an electron source 160 and an electron detector 170. The electron source 160 may be a miniature electron source, which has a smaller package size. For example, a suppressor cap housing may be 10 mm or less in dimension. In an instance, a miniature electron source has a microfabricated emitter structure. The electron source 160 is located on the column axis 156 of layered electron beam column 150 on the side of the layered electron beam column remote from sample holder 140. The electron source 160 provides electrons 162 to layered electron beam column 150. A voltage applied between electron source 160 and layered electron beam column 150 defines the initial beam energy of electron beam 152. In an instance, the electron detector 170 is mounted on a surface of layered electron beam column 150 facing sample holder 140 and generates an electron detection signal ES in response to electrons incident thereon. The layered electron beam column 150 and the sample holder 140 are arranged such that electron beam 152 in its undeflected state is incident at the center of sample holder 140 with the sample holder 140 at its home position.

The SEM 110 additionally includes a processor 190 that applies column control signals CC to layered electron beam column 150. Column control signals CC, at least some of which are in the kilovolt range, cause the layered electron beam column to perform such functions as extracting, accelerating, and collimating electrons 162, and focusing, blanking, and steering the electron beam 152. The processor 190 additionally receives electron detection signal ES from the electron detector 170.

The thinness of the layers constituting layered electron beam column 150 imposes limitations on the voltages of column control signals CC that can be applied within the electron beam column 150. These voltage limitations impose a limitation on the initial beam energy of electron beam 152. The highest initial beam energy of electron beam 152 output by an example of layered electron beam column 150 may be about 2 keV.

To identify a constituent atomic species of a sample using energy dispersive spectroscopy (EDS) means that the electron beam 152 is incident on the workpiece with a beam energy sufficiently high to generate x-rays at multiple wavelengths, but at least at two different wavelengths. The electron beam 152 at its initial beam energy of, for example, about 2 keV is capable of generating x-rays at multiple wavelengths from only the first 14 atomic species of the periodic table (i.e., hydrogen through nitrogen). Detecting and quantifying atomic species with atomic numbers greater than 14 is possible. Accordingly, spectroscopy apparatus 100 can additionally include auxiliary acceleration voltage (AAV) source 130 that provides spectroscopy apparatus 100 with the capability to perform EDS on samples containing atomic species with an atomic number greater than the atomic number corresponding to the initial beam energy of the electron beam 152.

The auxiliary acceleration voltage source 130 applies an acceleration voltage between the sample holder 140 and the layered electron beam column 150. Specifically, the auxiliary acceleration voltage source 130 sets the sample holder 140 to a more positive voltage than layered electron beam column 150. The auxiliary acceleration voltage accelerates the electron beam 152 to a final beam energy. At its final beam energy, the electron beam 152 can generate x-rays at multiple wavelengths from a larger range of atomic species than electron beam 152 at its initial beam energy. A range of atomic species includes the atomic species with consecutive atomic numbers between hydrogen and the atomic species with the highest atomic number from which the electron beam at its final beam energy can generate x-rays at multiple wavelengths. The auxiliary acceleration voltage is not subject to the maximum voltage limitations of layered electron beam column 150, and can be made as large as is necessary for the range of atomic species from which the electron beam 152 at its final beam energy is capable of generating x-rays at multiple wavelengths to include the highest atomic weight atomic species of interest.

In an example, a final beam energy of 15 keV is used to generate x-rays at multiple wavelengths from the highest atomic weight atomic species of interest, and the initial beam energy of electron beam 152 is 2 keV. In this example, auxiliary acceleration voltage source 130 applies an auxiliary acceleration voltage of 13 kV between sample holder 140 and layered electron beam column 150. With such an auxiliary acceleration voltage applied between sample holder 140 and layered electron beam column 150, the landing energy of electron beam 152 at the sample is 15 keV and the range of atomic species from which electron beam 152 can generate x-rays at multiple wavelengths is comparable with that of a conventional SEM operating with a beam energy of 15 keV.

In an example, the SEM 110 additionally includes an armature (not shown) to which electron source 160, layered electron beam column 150, sample holder 140, and x-ray detector 120 are coupled. The armature defines the spatial relationship among the electron source 160, the layered electron beam column 150, the sample holder 140, and the x-ray detector 120. In FIG. 1, the sample holder 140 includes a sample platform 142 that is electrically insulated from the armature, and, thus, from the remaining components of SEM 110, by an insulator 144 interposed between the sample platform and the armature. In FIG. 1, the sample holder 140 is mounted on a positioning stage 146. In an example, the positioning stage 146 is an XY stage that operates in response to stage control signals SC output by the processor 190 to move the sample holder 140 in the x-y plane relative to layered electron beam column 150. Positioning the stage 146 moves the sample holder 140 over a greater range of motion in the x-y plane than the range of motion obtained by the layered electron beam column 150 steering the electron beam 152. In another embodiment, the positioning stage 146 is an XYZ stage that operates in response to stage control signals SC additionally to move the sample holder 140 in the z-direction parallel to the column axis 156. In yet another embodiment, the positioning stage 146 additionally operates in response to stage control signals SC to rotate the sample holder 140 about an axis parallel to the column axis and/or to tilt the sample holder 140 about an axis parallel to the x-y plane. In other examples, the sample holder 140 is mounted on the armature in a fixed position relative to the layered electron beam column 150.

The SEM 110 and x-ray detector 120 are housed within a vacuum chamber 180. In an example, a wall (not shown) divides the vacuum chamber into an ultra-high vacuum (UHV) section (not shown) and a high vacuum (HV) section (not shown). The wall includes an isolation valve (not shown) located on column axis 156. The electron source 160, layered electron beam column 150, and electron detector 170 can be located within the UHV section, and the x-ray detector 120 and sample holder 140 can be located within the HV section. The vacuum chamber 180 is differentially pumped to maintain a pressure of typically 10⁻⁹ to 10⁻¹⁰ Torr within the UHV section, and to maintain a pressure of typically 10⁻⁶ to 10⁻⁷ Torr within the HV section during scanning electron microscopy and/or energy dispersive spectroscopy operations. The isolation valve can be moved into position to allow the HV section to be vented to the atmosphere to exchange samples while maintaining the ultrahigh vacuum within the UHV section. The other section is then evacuated to high vacuum prior to spectroscopy apparatus 100 being used to perform scanning electron microscopy and/or energy dispersive spectroscopy operations. Because of the small dimensions of the SEM 110, the dimensions of the vacuum chamber 180 are correspondingly small and only a few minutes to are needed to evacuate the HV section of the vacuum chamber 180 to its operating pressure.

In some embodiments of the spectroscopy apparatus 100, an electron beam column lacking the layered structure of layered electron beam column 150, but subject to a voltage limitation that limits the electron beam output by the electron beam column to an initial beam energy incapable of generating x-rays at multiple wavelengths from atomic species having atomic numbers greater than a threshold atomic number is substituted for the electron beam column 150. In such an embodiment, the auxiliary acceleration voltage source 130 applies an auxiliary acceleration voltage between the electron beam column and the sample holder 140 to accelerate the electron beam 152 to a final beam energy at which the electron beam can generate x-rays at multiple wavelengths from atomic species having atomic numbers greater than the threshold atomic number.

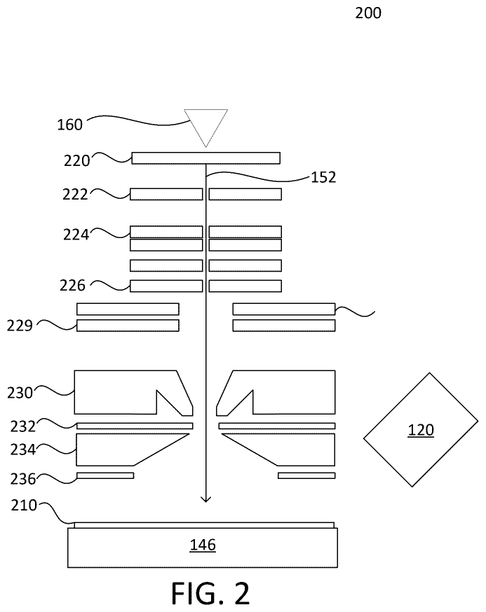

FIG. 2 is a diagram of an embodiment of an electron beam system 200. Some of the components in the electron beam system 200 of FIG. 2 can be part of the layered electron beam column 150 of FIG. 1. Thus, the components in FIG. 2 can be used within the electron beam system 100 in FIG. 1. For ease of illustration, not all the components in FIG. 1 are illustrated in FIG. 2. Like in FIG. 1, the electron source 160 in FIG. 2 generates an electron beam 152. An extractor 220 may be used to form the electron beam 152. The extractor 220 is between the electron source 160 and the magnetic objective lens 230 along the path of the electron beam 152. A stage 146 holds a workpiece 210 (e.g., a semiconductor wafer) in a path of the electron beam 152. The stage 146 can include other components of the sample holder 140. The workpiece 210 may have a positive bias applied using a power source in electronic communication with the stage 146, such as the auxiliary acceleration voltage source 130. During operation, the electron beam 152 may have a landing energy from 10 kV to 30 kV. The electron beam 152 can provide a field of view of at least 70 μm.

A magnetic objective lens 230 is disposed in the path of the electron beam 152. The magnetic objective lens 230 can include one or more permanent magnets. The objective lens field strength can vary given the particular needs of the application (e.g., approximately 0.1-0.15 T), but may be higher (e.g., approximately 1T) if needed. The overall dimensions can vary given the field strength required, and may vary from approximately 5 mm to 25 mm. The aperture dimension may be controlled to ensure a high collection efficiency if the detector is behind the lens. In an embodiment the aperture is 2 mm diameter, but may vary from approximately 0.25 mm diameter to 2 mm diameter. The shape of the objective lens 230 may be optimized for engineering the ideal magnetic field, such as peak field, shape, and location.

A focus element 236 is disposed in a path of the electron beam 152 between the magnetic objective lens 230 and the stage 146. The focus element 236 may be a dynamic focus element that adjusts the voltages to change the focus and/or field at the workpiece 210. Dynamic focus can refer to the ability to change focus voltage as a function of beam deflection. This corrects for field curvature effects seen in electron beam systems with larger field-of-view (FOV). Use of a magnetic objective lens 230 and focus element 236 can provide improved resolution at high landing energies while allowing adjustments to the extraction field. In general, the focus element 236 does not impede the return path of the backscattered electrons and is optimized for the use case. In an embodiment, the geometry of the focus element 236 is thin to allow for a reasonable working distance to the workpiece 210, and the aperture is as wide as possible to improve the collection angle of the backscattered electrons. Voltage ranges can vary so long as it does not cause breakdown for a given geometry.

The electron beam system 200 also can include a condenser lens 222 downstream of the extractor 220 along the path of the electron beam 251. Source deflectors 224 may be positioned downstream of the condenser lens 222 along the path of the electron beam 152. Upper deflector 228 and lower defector 229 may be positioned downstream of the source deflectors 224 along the path of the electron beam 152.

A backscattered electron detector 234 is disposed in the path of the electron beam 152 between the focus element 236 and the magnetic objective lens 230. Thus, the backscattered electron detector 234 sits below the magnetic objective lens 230 to capture backscattered electrons from the workpiece 210. In an instance, the backscattered electron detector 234 is segmented. The backscattered electron detector 234 can be segmented radially or concentrically (e.g., four quadrants or four concentric toruses). This can provide angular information or left/right/top/bottom information of the sample. More than four segments are possible.

In an instance, the backscattered electron detector 234 defines an opening for the electron beam 152. The opening may have a first diameter proximate the magnetic objective lens 230 and a second diameter proximate the focus element 236. The second diameter is larger than the first diameter. The conical opening may be a simplification of the geometry to match the opening of the focus element and the magnetic lens element. It may not match perfectly or be conical if there is reasonable collection efficiency. The returned electron path spreads as it travels back through the column. The conical shape of the magnetic objective lens 230 ensures no electrons are lost to collisions with the lens walls.

A post-lens deflector 232 may be positioned between the magnetic objective lens 230 and the backscattered electron detector 234 along the path of the electron beam 152.

An x-ray detector 120 is configured to receive x-rays emitted from the workpiece 210 on the stage 146. In an instance, the x-ray detector 120 may be a silicon drift detector (SDD). The x-ray detector 120 may be positioned off-side to enable x-ray imaging. The x-ray detector 120 may be angled relative to a surface of the workpiece 210.

The geometry and location of the backscattered electron detector 234 may be chosen to optimize collection of backscattered electrons. The backscattered electron detector 234 can be a scintillator and photomultiplier tube (PMT), hybrid scintillator and solid-state detector (e.g., a PIN diode), a PIN diode, avalanche diode (APD), or a micro-channel plate. The backscattered electron detector 234 and x-ray detector 120 may be supplemented for addition detection. For example, the electron beam system 200 may have up to three detector types: in-line in the middle of the layered electron beam column 150; the backscattered electron detector 234 at the bottom of the layered electron beam column 150, and the x-ray detector 120 offsides of the layered electron beam column 150. Thus, a secondary electron and backscattered electron detector 226 may be disposed in the path of the electron beam 152 between the extractor 220 and the magnetic objective lens 230. The secondary electron and backscattered electron detector 226 may be the same type of detector or a different type of detector than the backscattered electron detector 234. The secondary electron and backscattered electron detector 226 may be a PIN diode, hybrid scintillator detector (e.g., scintillator with photomultiplier tube or diode), avalanche diode, microchannel plate, charge-coupled device (CCD), or other detectors.

The processor 190 may be in electronic communication with at least the backscattered electron detector 234 and the x-ray detector 120 of FIG. 2. The processor 190 also may be in electronic communication with the secondary electron and backscattered electron detector 226 of FIG. 2. The processor 190 typically comprises a programmable processor, which is programmed in software and/or firmware to carry out the functions that are described herein, along with suitable digital and/or analog interfaces for connection to the other elements of the electron beam system 200. Alternatively or additionally, the processor 190 comprises hard-wired and/or programmable hardware logic circuits, which carry out at least some of the functions of the processor 190. Although the processor 190 is shown in FIG. 1, for the sake of simplicity, as a single, monolithic functional block, in practice the processor 190 may comprise multiple, interconnected control units, with suitable interfaces for receiving and outputting the signals that are illustrated in the figures and are described in the text. Program code or instructions for the processor 190 to implement various methods and functions disclosed herein may be stored in readable storage media, such as a memory in the processor 190 or other memory.

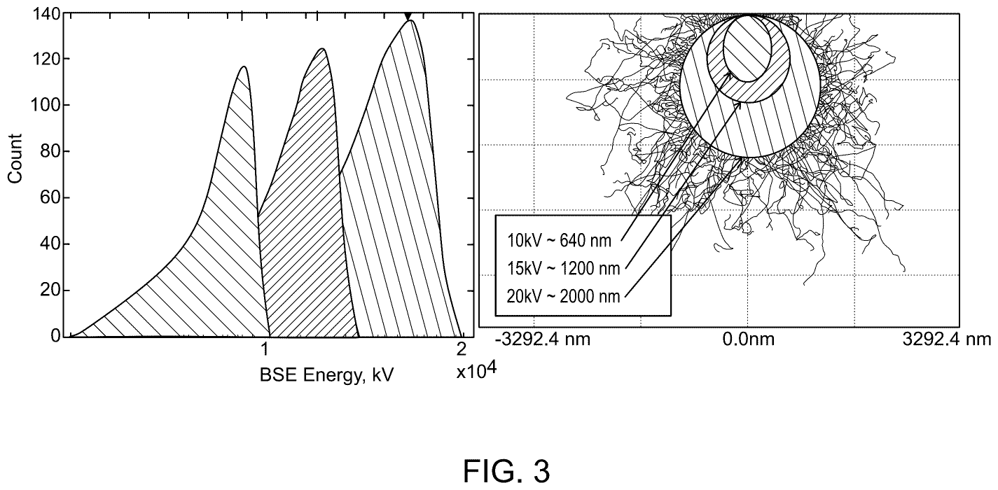

FIG. 3 is a distribution of backscattered electron modeling used in an example and resulting backscattered electron penetration depths. The vertical axis of the right chart ranges from 0.0 nm at the top to 4000.0 nm at the bottom. As shown in FIG. 3, the peak energy of backscattered electron distribution is slightly below the initial landing energy with a skewed distribution towards lower energies. The higher the landing energy, then the larger the interaction volume with the workpiece and the deeper the penetration or interrogation depth of the workpiece. BSE collection efficiency (e.g., approximately 25% to 3%) generally decreases as a function of working distance (e.g., 1-10 mm) and landing energy (e.g., 10-30 kV). Despite this, there can be sufficient signal for amplification. The signal may be proportional to collection efficiency*beam current*backscattered yield. These ranges are provided for a particular design geometry simulated. Other ranges are possible.

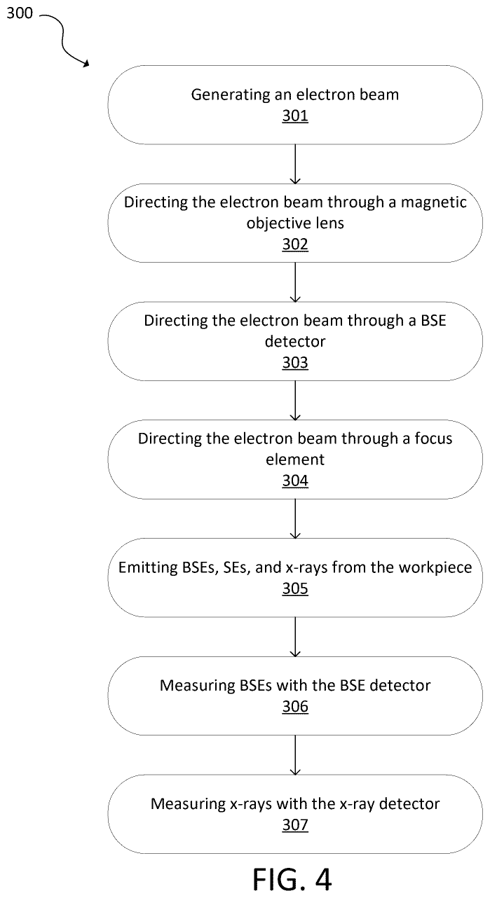

FIG. 4 is a flowchart of a method 300. The method 300 can be performed on an embodiment of the electron beam system 200 in FIG. 2. At 301, an electron beam is generated using an electron source. The electron beam may have an initial beam energy. The electron beam is directed through a magnetic objective lens at 302, through a backscattered electron detector disposed downstream of the magnetic objective lens at 303, and through a focus element disposed downstream of the backscattered electron detector at 303. The magnetic objective lens can include a permanent magnet.

Backscattered electrons (BSEs), secondary electrons (SEs), and x-rays are emitted from a workpiece disposed on a stage downstream of the focus element at 305. The backscattered electrons are measured with the backscattered electron detector at 306. The x-rays can be measured with an x-ray detector at 307. An image of the workpiece can be determined from at least the backscattered electrons and x-rays using a processor.

The electron beam also may be directed through an extractor disposed in the path of the electron beam between the electron source and the magnetic objective lens and through a secondary electron and backscattered electron detector disposed in the path of the electron beam between the extractor and the magnetic objective lens. Secondary electrons and the backscattered electrons may be measured with the secondary electron and backscattered electron detector. These measurements can be used to generate the image of the workpiece.

A positive bias may be applied to the workpiece (e.g., a semiconductor wafer). A high positive wafer bias can accelerate the electron beam to its final beam energy at the workpiece. At this final beam energy, the electron beam can generate the backscattered electrons and x-rays.

The electron beam system may be capable of providing a landing energy from 10 kV to 30 kV, from 15 kV to 30 kV, or from 20 kV to 30 kV. The landing energy may be, for example, approximately 10 kV, 15 kV, or 20 kV. This landing energy can be coupled with the detection of the backscattered electrons. The wide landing energy range can enable detection of buried features at various depths within the sample, such as depths of approximately 2000 nm as demonstrated in FIG. 3. A working distance can be from approximately 1.5 mm to 8 mm to enable varying extraction fields between the column and the workpiece.

The electron beam can provide a field of view (FOV) of at least 70 μm with a spot size of at least 7 nm. The field of view and spot size may be relatively insensitive across the landing energy operating range.

The layered electron beam column can output an electron beam towards the workpiece at an initial beam energy. A positive wafer bias at the workpiece then accelerates the electron beam to its final beam energy at the workpiece. At the final beam energy, the electron beam can generate secondary electrons, backscattered electrons, and x-rays. The primary electron beam may be raster scanned over the workpiece. The secondary electrons and backscattered electrons can return along the primary electron beam path toward the detector(s), which may be positioned around the path of the electron beam. The backscattered electrons may primarily hit the lower detector, though a portion may pass to other detectors. The x-rays that are generated may go to off-side detectors. The returning electrons can impact the detector(s) at different locations. Depending on where the primary beam raster scanned the workpiece, a signal of varying intensity can be captured. A read out of the detector signal can be performed via an amplifier circuit directly adjacent to the detector to minimize noise.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
an electron source that generates an electron beam;
a stage configured to hold a workpiece in a path of the electron beam;
a magnetic objective lens disposed in the path of the electron beam;
a focus element disposed in the path of the electron beam between the magnetic objective lens and the stage; and
a backscattered electron detector disposed in the path of the electron beam between the focus element and the magnetic objective lens.

2. The system of claim 1, further comprising an extractor disposed in the path of the electron beam between the electron source and the magnetic objective lens.

3. The system of claim 2, further comprising a secondary electron and backscattered electron detector disposed in the path of the electron beam between the extractor and the magnetic objective lens.

4. The system of claim 1, wherein the workpiece has a positive bias applied using a power source.

5. The system of claim 1, wherein the magnetic objective lens includes a permanent magnet.

6. The system of claim 1, wherein the backscattered electron detector defines an opening for the electron beam, wherein the opening has a first diameter proximate the magnetic objective lens and a second diameter proximate the focus element, wherein the second diameter is larger than the first diameter.

7. The system of claim 1, wherein the electron beam has a landing energy from 10 kV to 30 kV.

8. The system of claim 1, wherein the electron beam provides a field of view of at least 70 μm.

9. The system of claim 1, further comprising a processor in electronic communication with at least the backscattered electron detector.

10. The system of claim 1, further comprising an x-ray detector configured to receive x-rays emitted from the workpiece on the stage.

11. A method comprising:
generating an electron beam with an electron source;
directing the electron beam through a magnetic objective lens;
directing the electron beam through a backscattered electron detector disposed downstream of the magnetic objective lens in a path of the electron beam;
directing the electron beam through a focus element disposed downstream of the backscattered electron detector in a path of the electron beam;
emitting backscattered electrons, secondary electrons, and x-rays from a workpiece disposed on a stage downstream of the focus element; and
measuring the backscattered electrons with the backscattered electron detector.

12. The method of claim 11, further comprising determining an image of the workpiece from at least the backscattered electrons using a processor.

13. The method of claim 11, further comprising directing the electron beam through an extractor disposed in the path of the electron beam between the electron source and the magnetic objective lens.

14. The method of claim 13, further comprising:
directing the electron beam through a secondary electron and backscattered electron detector disposed in the path of the electron beam between the extractor and the magnetic objective lens; and
measuring the x-rays with an x-ray detector.

15. The method of claim 14, further comprising measuring the secondary electrons and the backscattered electrons with the secondary electron and backscattered electron detector.

16. The method of claim 11, further comprising applying a positive bias to the workpiece.

17. The method of claim 11, wherein the magnetic objective lens includes a permanent magnet.

18. The method of claim 11, wherein the backscattered electron detector defines an opening for the electron beam, wherein the opening has a first diameter proximate the magnetic objective lens and a second diameter proximate the focus element, wherein the second diameter is larger than the first diameter.

19. The method of claim 11, wherein the electron beam has a landing energy from 10 kV to 30 kV.

20. The method of claim 11, wherein the electron beam provides a field of view of at least 70 μm.
